(19) United States
(12) Patent Application Publication
(10) Pub. No.: US 2001/0052618 A1
(43) Pub. Date: Dec. 20, 2001

(54) Semiconductor device having a plurality of gate insulating films of different thicknesses, and method of manufacturing such semiconductor device

(75) Inventor: Eiji Hasegawa, Tokyo (JP)

Correspondence Address: YOUNG & THOMPSON, 745 SOUTH 23RD STREET 2ND FLOOR, ARLINGTON, VA, 22202

(73) Assignee: NEC Corporation

(21) Appl. No.: 09/883,373

(22) Filed: Jun. 19, 2001

(30) Foreign Application Priority Data
Jun. 20, 2000 (JP) 2000-185283

(51) Int. Cl. H01L 29/76; H01L 31/062; H01L 29/94

(52) U.S. Cl. 257/345; 257/371; 257/395

(57) ABSTRACT

A semiconductor device is fabricated by injecting fluorine into a region of a semiconductor substrate other than a region of the semiconductor substrate where a thinnest gate insulating film is to be formed, among a plurality of regions where gate insulating films are to be formed. Then, the semiconductor substrate with fluorine injected therein is oxidized to form an oxide film in the plurality of regions. A surface of the oxide film is nitrided to turn a surface layer thereof into an oxynitride film or form a nitride film on the surface of the oxide film. The semiconductor device has a plurality of gate insulating films of different thicknesses which contain nitrogen in their surface layers.

### BACKGROUND OF THE INVENTION

1. Field of the Invention

The present invention relates to a semiconductor device having a plurality of gate insulating films of different thicknesses, and a method of manufacturing such semiconductor device.

2. Description of the Related Art

For developing semiconductor devices, it is most important to form gate insulating films, which are an essential part of the semiconductor devices, with high reliability and at a desired film thickness. Recently available logic MIS (metal-insulator-silicon) devices have a thin gate insulating film comprising an oxide film whose thickness is 3.0 nm or less in order to lower the operating current of the transistor. As the gate insulating film becomes thinner, however, a leakage current from the gate electrode increases, and an impurity tends to be diffused from the gate electrode into the semiconductor substrate.

One solution to the problem of the increasing leakage current from the gate electrode is that a material having a high permittivity is used as a gate insulating film instead of a silicon oxide film. Materials having a high permittivity include a nitride film and an oxynitride film which comprises an oxide film with nitrogen introduced therein. If a gate insulating film comprises a nitride film or an oxynitride film, then since the permittivity thereof is greater than the permittivity of an oxide film depending on the amount of introduced nitrogen, it is possible to make the gate insulating film thicker than the oxide film provided they have the same capacitance. The thick gate insulating film is capable of reducing a direct tunnel current, i.e., a leakage current flowing via the gate insulating film. The gate insulating film containing nitrogen is also effective in preventing an impurity of boron from being diffused into the semiconductor substrate. For these reasons, it is believed in the art of semiconductor devices that use of a nitride film or an oxynitride film is promising to realize a gate insulating film having a thickness of 2.0 nm or less.

The main stream of semiconductor device fabrication is presently a technology for fabricating a plurality of semiconductor devices of different functions and purposes on one wafer. The semiconductor devices of different types included in a wafer often have gate insulating films of different thicknesses. For example, a core transistor that is required to perform high-speed switching needs a gate insulating film having a thickness of 1.5 nm, whereas an interface device for connection to an external device requires a gate insulating film having a greater thickness of about 4.5 nm to meet higher power supply voltage requirements. Some semiconductor devices of other functions may require gate insulating films of other thicknesses.

For fabricating a plurality of types of semiconductor devices on one wafer, it is necessary that a plurality of types of gate insulating films of different thicknesses be simultaneously formed on the wafer. To meet such a need, it is important to form gate insulating films of different thicknesses simply without causing a reduction in the performance and reliability of each of the semiconductor devices.

Some conventional processes of simultaneously forming a plurality of types of gate insulating films of different thicknesses and their problems will be described below.

Conventional process A

The conventional process A employs a process of forming oxide films of different thicknesses using an accelerated oxidizing effect based on fluorine injection and a process of forming a thin oxynitride film according to an oxidizing and nitriding method using an NO gas. The conventional process A as it is used to form two types of gate insulating films of different thicknesses on one substrate will be described below with reference to FIGS. 1a through 1e of the accompanying drawings.

As shown in FIG. 1a, semiconductor substrate 101 includes first region 101a where a gate insulating film of a greater thickness is to be formed and second region 101b where a gate insulating film of a smaller thickness is to be formed. Photoresist layer 102 is formed only on second region 101b by usual photoresist coating, exposing, and developing steps.

Then, as shown in FIG. 1b, fluorine is injected into the assembly by ion implantation under the conditions of an electric field of 3 keV for fluorine ion acceleration and a dose of 5×10¹⁴ atoms/cm². Fluorine atoms 103 are now introduced into exposed first region 101a of semiconductor substrate 101 where no photoresist layer 102 is present. Over second region 101b, fluorine atoms 103 are introduced into photoresist layer 102.

Then, photoresist layer 102 is removed by a dedicated chemical liquid, and thereafter the assembly is cleaned in preparation for the formation of an oxide film. For example, the assembly is cleaned in a primary cleaning stage using a mixed solution of ammonium hydroxide and then in a secondary cleaning stage using a mixed solution of sulfuric acid and hydrogen peroxide. When the assembly is thus cleaned, as shown in FIG. 1c, chemical oxide film (natural oxide film) 104 having a thickness of about 1.0 nm is formed all over the surface of semiconductor substrate 101. Chemical oxide film 104 may be removed in a subsequent step, if necessary.

Then, the assembly is thermally oxidized under such conditions that a thermal oxide film is formed to a thickness of 1.6 nm in second region 101b. For example, if the assembly is heated by a batch-type lamp heating device under a pressure of 50 Torr or lower at a temperature of 950° C. for 9 seconds, then as shown in FIG. 1d, thermal oxide film 105 is formed on semiconductor substrate 101 to a thickness of 1.6 nm in second region 101b and a thickness of 2.1 nm in first region 101a. Therefore, the difference between the thicknesses of thermal oxide film 105 in first region 101a and second region 101b is 0.5 nm.

The assembly is then heated using an NO gas. For example, the assembly is heated using 2 SLM of an NO gas under a pressure of 100 Torr at a temperature of 1000° C. for 30 seconds, thus nitriding thermal oxide film 105. Nitrogen from the NO gas is diffused into thermal oxide film 105 and reaches the interface between thermal oxide film 105 and semiconductor substrate 101. As shown in FIG. 1e, a portion of thermal oxide film 105 near the interface between thermal oxide film 105 and semiconductor substrate 101 is turned into oxynitride film 106. Oxynitride film 106 and thermal oxide film 105 jointly make up gate insulating film 107. Oxynitride film 106 has a nitrogen concentration of about 5%.

Since gate insulating film 107 includes oxynitride film 106, the permittivity of gate insulating film 107 in its entirety is larger than the permittivity of a gate insulating film which comprises an oxide film only. Actually, the permittivity of a thermal oxide film is 3.9 whereas the permittivity of an oxynitride film is about 4.3.

Subsequently, polysilicon is deposited and photoresist processing is carried out to form a gate electrode on gate insulating film 107, and a source and a drain are formed to produce a transistor structure. The thickness of actually fabricated gate insulating film 107 is 2.1 nm in first region 101a and 1.6 nm in second region 101b. From the standpoint of transistor operating currents, these thicknesses of first and second regions 101a, 101b correspond respectively to 1.5 nm and 2.0 nm in terms of the thicknesses of oxide films. A transistor fabricated on first region 101a is preferably used as a high-speed transistor, and a transistor fabricated on second region 101b is preferably used as an SRAM transistor. Therefore, a high-speed transistor and an SRAM transistor can simultaneously formed on one wafer according to the conventional process A.

However, while the conventional process A can provide a sufficient film thickness difference, the oxynitride film formed at the interface between the thermal oxide film and the semiconductor substrate by the heat treatment using the NO gas poses some problems. Specifically, nitrogen that is present at the interface between the thermal oxide film and the semiconductor substrate brings about a defect referred to as an interface state at the interface. When the interface state is created, since charges are exchanged via the interface state, it not only impairs the reliability of the gate insulating film, but also scatters a carrier flowing through the channel of the transistor, lowering the mobility of the carrier. As a result, the ON current of the transistor is reduced, preventing the semiconductor device from operating at higher speeds. Since nitrogen is present only in the interface between the thermal oxide film and the semiconductor substrate, an impurity tends to be diffused from the gate electrode into the gate insulating film. Though the impurity, e.g., boron, is prevented from being diffused by the area containing nitrogen, as the area containing nitrogen is positioned in the interface between the thermal oxide film and the semiconductor substrate, the impurity enters the oxide film and is accumulated therein. The entry of the impurity is responsible for reducing the reliability of the gate insulating film.

Conventional process B

The conventional process B attempts to solve the above problems by spacing the area of the gate insulating film which contains nitrogen away from the interface between the thermal oxide film and the semiconductor substrate. The conventional process B will be described below with reference to FIGS. 2a through 2c of the accompanying drawings which show the structure of a gate insulating film after fluorine has been injected thereinto.

In order to have nitrogen located in a position spaced from the interface between the thermal oxide film and the semiconductor substrate according to the oxidizing and nitriding method using the NO gas, it is necessary to form a nitride layer on the surface of the semiconductor substrate and thereafter oxidize the nitride layer in an oxygen atmosphere to produce a new oxide layer beneath the nitride layer.

As shown in FIG. 2a, fluorine atoms 113 are injected into first region 111a of semiconductor substrate 111 as according to the conventional process A. After the assembly is cleaned, as shown in FIG. 2b, oxynitride film 114 is formed on the surface of semiconductor substrate 111 in an NO gas atmosphere. Thereafter, oxynitride film 114 is heated in an oxygen atmosphere to produce a gate insulating film structure having oxide film 115 beneath oxynitride film 114, as shown in FIG. 2c. For example, oxynitride film 114 having a thickness which corresponds to 0.8 nm in terms of the thicknesses of oxide films is formed in the presence of an NO gas by heat treatment at 850° C. for 120 seconds, and thereafter heated under oxidizing conditions of a dry oxygen atmosphere at 1050° C. for 30 seconds, thereby forming a gate insulating film having a total thickness of 1.5 nm. The gate insulating film is of a double-layer structure including an upper layer comprising oxynitride film 114 whose thickness corresponds to 0.8 nm in terms of the thicknesses of oxide films and a lower layer comprising oxide film 115 having a thickness of 0.7 nm.

The conventional process B, however, suffers the following disadvantages:

In the region where fluorine is injected, i.e., first region 101a, the film thickness does not increase essentially, and hence the injection of fluorine is not effective enough. The effect of increasing the film thickness by introducing fluorine is based on an increase in the oxidizing rate with fluorine. However, if an oxynitride film is initially formed using an NO gas in the process of forming a gate insulating film, then substantially no effect of increasing the film thickness takes place. This is because nitriding simultaneously progresses in the presence of the NO gas and hence the rate of film growth is low, and fluorine atoms 113 tend to evaporate from semiconductor substrate 111 during the nitriding process, resulting in substantially no effect of increasing the film thickness with the nitriding process. In the example shown in FIGS. 2a through 2c, the increase in the film thickness in first region 111a with respect to second region 111b is only 0.1 nm. Therefore, it is impossible to form a gate insulating film having a widely different film thickness based on the injection of fluorine.

Another problem is that when the oxynitride film is subsequently oxidized, nitrogen in the initially formed oxynitride film is removed, and hence the concentration of nitrogen is not increased. If the concentration of nitrogen is not sufficient, then boron enters the oxynitride film, reducing its reliability. If boron reaches semiconductor substrate 111, then the threshold voltage changes, introducing difficulties into the design of the semiconductor device.

Conventional Process C

The conventional process C attempts to eliminate the above drawbacks by forming an oxide film on the surface of the semiconductor substrate after fluorine has been introduced into the semiconductor substrate, thereby oxidizing and nitriding the oxide film with an NO gas, and then oxidizing the film again. According to the conventional process C, the effect of increasing the film thickness is achieved by the first oxidizing step, then the oxynitride film is formed, and the subsequent oxidizing step is carried out to displace the oxynitride film formed in the interface between the oxide film and the semiconductor substrate to a position that is spaced from the interface as widely as possible, i.e., to form an oxide film in the interface between the oxide film and the semiconductor substrate. The complex process is made possible if the thinnest gate insulating film has a thickness of about 3.0 nm. Actually, however, in a region of a small film thickness, e.g., a film thickness of 2.5 nm or less, which requires a nitride film for the purpose of reducing a leakage current via the gate insulating film, it is not possible to form a substantially thick oxide film in the first oxidizing step, and hence to develop no sufficient film thickness difference. In addition, inasmuch as the amount of introduced nitrogen is small in the next oxidizing and nitriding step, and the final oxidizing step is performed sufficiently, the oxynitride film is not displaced far enough away from the interface. As a result, the diffusion of impurities is not fully suppressed, and the resulting transistor is liable to have reduced reliability and fail to exhibit sufficient performance.

### SUMMARY OF THE INVENTION

It is an object of the present invention to provide a semiconductor device having a plurality of gate insulating films of different thicknesses, which contains no impurity having reached a semiconductor substrate, is highly reliable, and has a large film thickness difference, and a method of manufacturing such semiconductor device.

To achieve the above object, according to a method of manufacturing a semiconductor device in accordance with the present invention, fluorine is injected into a region of a semiconductor substrate other than a region of the semiconductor substrate where a thinnest gate insulating film is to be formed, among a plurality of regions where gate insulating films are to be formed. Then, the semiconductor substrate with fluorine injected therein is oxidized to form an oxide film in the plurality of regions. In the region where fluorine has been injected, the thickness of the oxide film is greater than the thickness of the oxide film in the other regions. Then, a surface of the oxide film is nitrided to turn a surface layer thereof into an oxynitride film or form a nitride film on the surface of the oxide film. In this manner, gate insulating films including oxide films at an interface with the semiconductor substrate and containing nitrogen above the oxide films are formed in the respective regions of the semiconductor substrate. Since the oxide films in the region where fluorine has been injected and the region where no fluorine has been injected have different thicknesses, the gate insulating films also have different thicknesses in the respective regions.

According to the present invention, the gate insulating films provide sufficient thickness differences that allow transistors to be designed to suit various applications. Since sufficient nitrogen is present in the gate insulating films, any leakage current via the gate insulating films is blocked, thus reducing a standby current in a circuit in which the semiconductor device is used. Inasmuch as nitrogen contained in the gate insulating films is effective to prevent an impurity from being diffused from gate electrodes, the threshold voltage is prevented from varying, thus preventing the gate insulating films from becoming less reliable. As nitrogen is present in the vicinity of the surface of the gate insulating films, it prevents an interface state from taking place, with the result that the operating current, i.e., ON current, of the semiconductor device is prevented from being lowered. Thus, it is possible to fabricate semiconductor devices having a plurality of gate insulating films of different thicknesses, which are suitable for use in various applications, according to a relatively simple fabrication process at a reduced cost. The semiconductor devices have highly reliable characteristics and high performance, and can operate at a high speed.

In the above method of manufacturing a semiconductor device in accordance with the present invention, prior to the step of injecting fluorine, another oxide film than the above oxide film may be formed on the surface of the semiconductor substrate, and thereafter may be removed from the regions other than the region where the thickest gate insulating film is to be formed, thus increasing the thickness differences between the thickest gate insulating film and the other gate insulating films. After the first step of forming the oxide film, there may be added the step of forming a polysilicon film on the surface of the oxide film, and subsequent steps may be modified accordingly to form electrode layers on the gate insulating films.

A semiconductor device according to the present invention may be manufactured by the above method. The semiconductor device has a semiconductor substrate, a plurality of oxide films formed respectively in different regions in a surface of the semiconductor substrate to respective different thicknesses, and a plurality of oxynitride films or nitride films produced by nitriding surfaces of the oxide films.

The above and other objects, features, and advantages of the present invention will become apparent from the following description with reference to the accompanying drawings which illustrate examples of the present invention.

### BRIEF DESCRIPTION OF THE DRAWINGS

FIGS. 1a through 1e are fragmentary cross-sectional views illustrative of a conventional process of fabricating a semiconductor device having two types of gate insulating films of different thicknesses;

FIGS. 2a through 2c are fragmentary cross-sectional views illustrative of another conventional process of fabricating a semiconductor device having two types of gate insulating films of different thicknesses;

FIGS. 3a through 3e are fragmentary cross-sectional views illustrative of a process of fabricating a semiconductor device having two types of gate insulating films of different thicknesses according to a first embodiment of the present invention;

FIG. 4 is a fragmentary cross-sectional view of two transistor structures fabricated by the process according to the first embodiment of the present invention;

FIG. 5 is a graph showing current vs. voltage characteristics of a gate insulating film whose thickness corresponds to 1.5 nm in terms of the thickness of an oxide film, which is produced by the process according to the first embodiment of the present invention;

FIG. 6 is a graph showing a threshold voltage, as it varies from a theoretical value, of a p-MOS transistor which has the gate insulating film whose thickness corresponds to 1.5 nm in terms of the thickness of an oxide film, which is produced by the process according to the first embodiment of the present invention;

FIG. 7 is a graph showing the relationship between times up to breakdown and accumulated fault rates at the time electric stresses are continuously imposed on the gate insulating film whose thickness corresponds to 1.5 nm in terms of the thickness of an oxide film, which is produced by the process according to the first embodiment of the present invention;

FIG. 8 is a graph showing the relationship between fluorine doses and film thickness differences at the time oxide films are formed under constant oxidizing conditions and varying fluorine injecting conditions;

FIGS. 9a through 9e are fragmentary cross-sectional views illustrative of a process of fabricating a semiconductor device having two types of gate insulating films of different thicknesses according to a third embodiment of the present invention;

FIGS. 10a through 10d are fragmentary cross-sectional views illustrative of a process of fabricating a semiconductor device having three types of gate insulating films of different thicknesses according to a fourth embodiment of the present invention;

FIGS. 11a through 11e are fragmentary cross-sectional views illustrative of a process of fabricating a semiconductor device having three types of gate insulating films of different thicknesses according to a fifth embodiment of the present invention; and

FIGS. 12a through 12f are fragmentary cross-sectional views illustrative of a process of fabricating a semiconductor device having three types of gate insulating films of different thicknesses according to a sixth embodiment of the present invention.

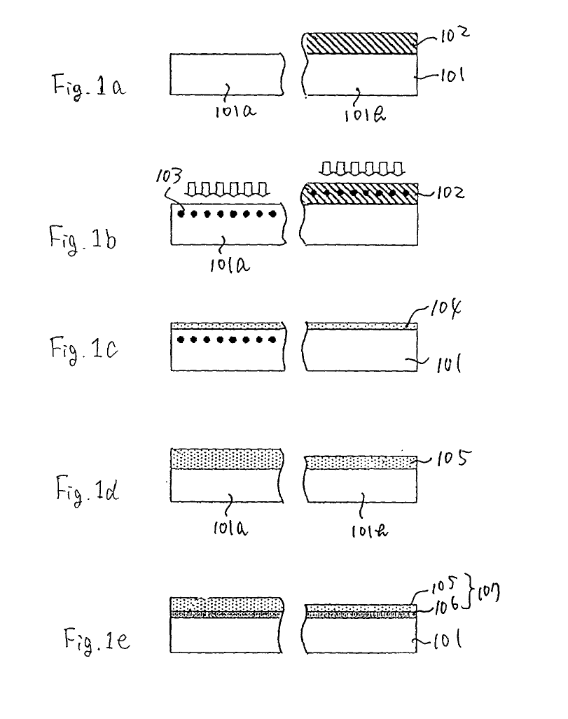

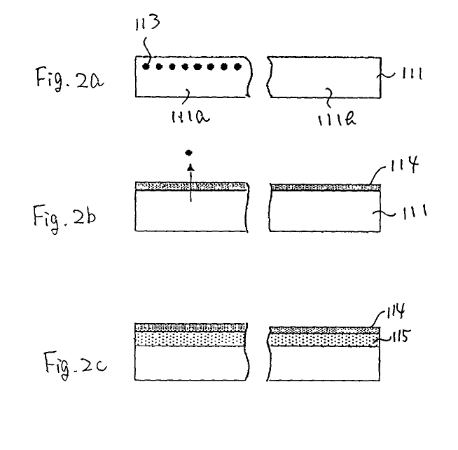

### DESCRIPTION OF THE PREFERRED EMBODIMENTS

1st Embodiment

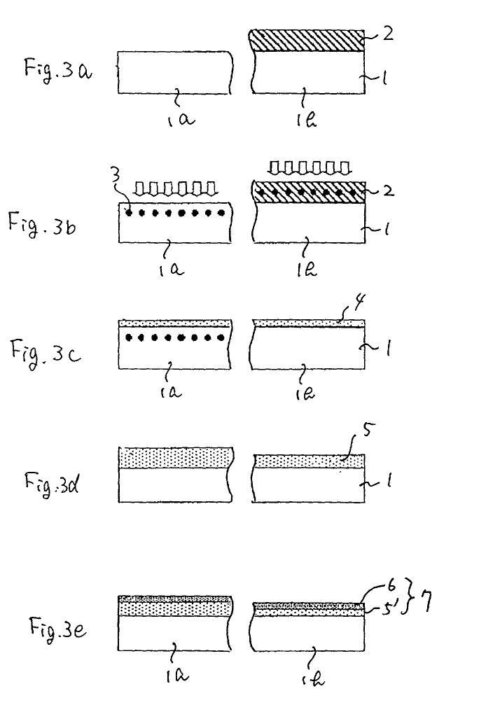

A process of fabricating two types of gate insulating films of different thicknesses on one wafer according to a first embodiment of the present invention will be described below with reference to FIGS. 3a through 3e. Gate insulating films of different thicknesses are formed in respective regions, which may be disposed either adjacent to each other or remotely from each other according to the present invention, on one wafer. In the present embodiment, the formation of a gate insulating film having a thickness of 2.0 nm and a gate insulating film having a thickness of 1.5 nm will be described below. These thicknesses correspond to values in terms of the thicknesses of oxide films, and may be of different values according to the present invention.

As shown in FIG. 3a, as with the conventional process A, silicon substrate 1 includes first region 1a where a gate insulating film of a greater thickness is to be formed and second region 1b where a gate insulating film of a smaller thickness is to be formed. Photoresist layer 2 is formed only on second region 1b.

Then, as shown in FIG. 3b, fluorine is injected into the assembly by ion implantation under the same conditions as those in the conventional process A. Fluorine atoms 3 are now introduced into silicon substrate 1 in first region 1a and into photoresist layer 2 over second region 1b.

Then, as shown in FIG. 3c, a chemical oxide film (natural oxide film) 4 having a thickness of about 1.0 nm is formed all over silicon substrate 1 as according to the conventional process A.

Then, as shown in FIG. 3d, the assembly is thermally oxidized to form thermal oxide film 5 on the surface of silicon substrate 1 as according to the conventional process A under such conditions that thermal oxide film 5 has a thickness of 1.7 nm in second region 1b. Thermal oxide film 5 has a thickness of 2.2 nm in first region 1a, with the difference between thethicknesses of thermal oxide film 5 in first region 1a and second region 1b being 0.5 nm.

Then, the surface of thermal oxide film 5 is nitrided to turn a surface layer thereof into oxynitride film 6, as shown in FIG. 3e. The surface of thermal oxide film 5 may be nitrided by introducing radical nitrogen or active nitrogen excited by a plasma generating apparatus into thermal oxide film 5, for example. When the temperature is kept at 500° C. and radical nitrogen or active nitrogen is introduced with an energy of 3 kW for 30 seconds, nitrogen enters the surface layer of thermal oxide film 5 to a depth of about 1.0 nm from its surface, thus turning the surface layer into oxynitride film 6. Thermal oxide film 5′ with oxynitride film 6 in its surface serves as gate insulating film 7. The concentration of nitrogen in oxynitride film 6 is about 20%.

Because of oxynitride film 6, gate insulating film 7 has a total permittivity greater than the permittivity of oxide film 5 shown in FIG. 3d. In reality, oxide film 5 shown in FIG. 3d as a permittivity of 3.9, whereas gate insulating film 7 has a permittivity of about 5.0. The thickness of gate insulating film 7 in first region 1a corresponds to 1.5 nm in terms of the thickness of an oxide film, and the thickness of gate insulating film 7 in second region 1b corresponds to 2.0 nm in terms of the thickness of an oxide film.

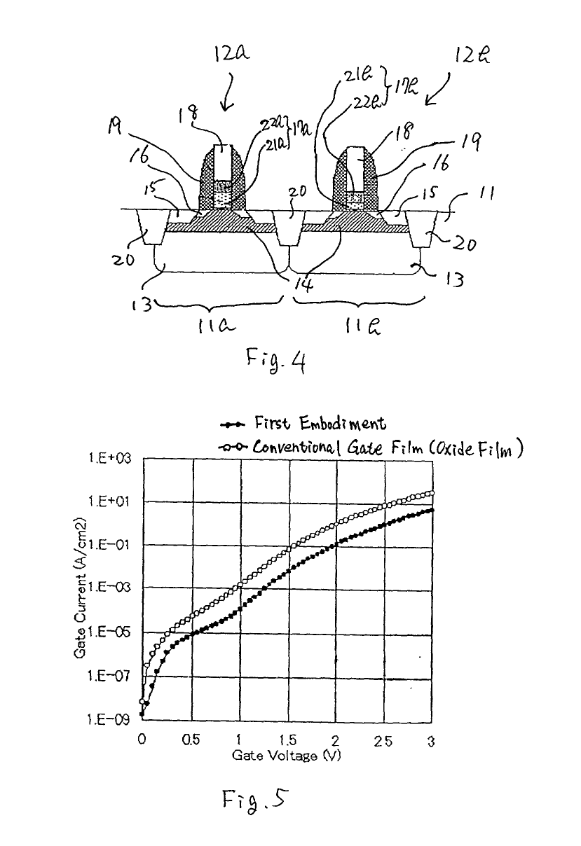

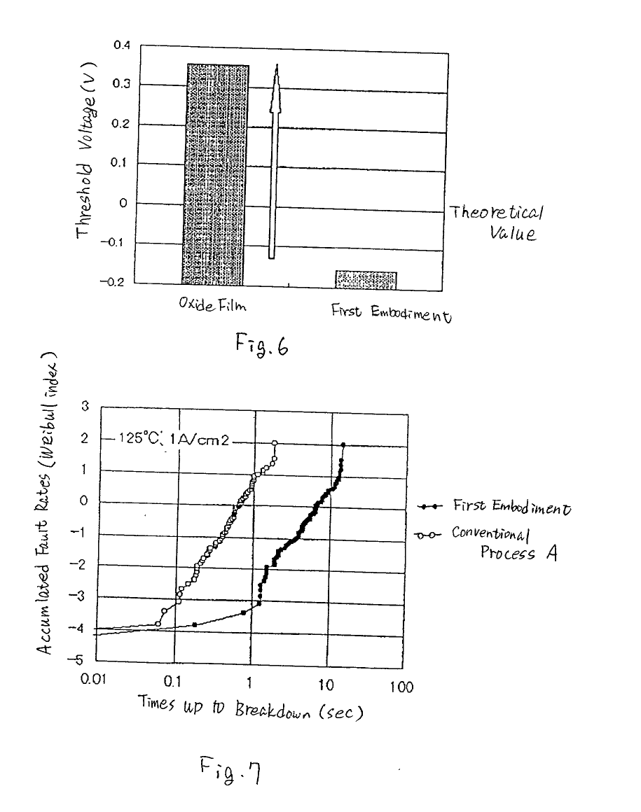

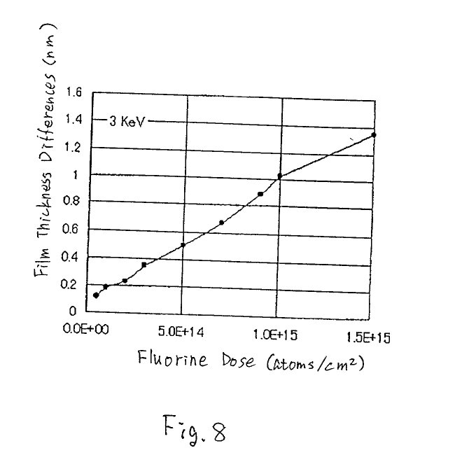

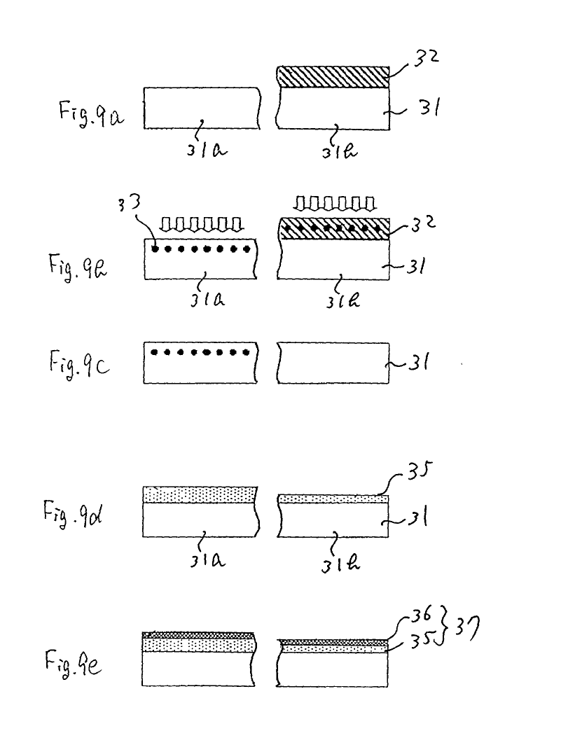

Subsequently, the assembly is processed by usual steps of fabricating a transistor to form transistors on silicon substrate 1. FIG. 4 shows in cross section transistor structures fabricated according to the above process.

In FIG. 4, two transistors 12a, 12b are formed on semiconductor substrate 11. Transistor 12a is formed in first region 11a, and transistor 12b is formed in second region 11b. First and second regions 11a, 11b are separated from each other by device separator 20 that is formed according to an STI (Shallow Trench Isolation) technology. In respective regions 11a, 11b, there are formed wells 13 including well injection layers 14 in a surface layer of semiconductor substrate 11. Source/drain diffusion layers 15 are disposed on both sides of the surface layer of each of wells 13. Pocket injection layers 16 are disposed inwardly of source/drain diffusion layers 15. On the surface of semiconductor substrate 11, gate insulating films 17a, 17b are formed in respective regions 11a, 11b, and polysilicon electrodes 18 are formed as gates on gate insulating films 17a, 17b, respectively. Insulating film side walls 19 are disposed on both sides of gate insulating films 17a, 17b and polysilicon electrodes 18.

Gate insulating films 17a, 17b are constructed of respective oxide films 21a, 21b and respective oxynitride films 22a, 22b. Oxide films 21a, 21b have different thicknesses in transistor 12a in first region 11a and transistor 12b in second region 11b. Thus, gate insulating films 17a, 17b have different thicknesses.

Transistors 12s, 12b have different functions depending on the thicknesses of gate insulating films 17a, 17b. For example, if gate insulating film 17b has a thickness of 1.5 nm, then transistor 12b functions as a high-speed transistor and has a low drive voltage of 1.0 V. If gate insulating film 17a has a thickness of 2.0 nm, then transistor 12a functions as an SRAM transistor and has a drive voltage of 1.2 V.

Advantageous effects provided by the first embodiment of the present invention will be described below.

FIG. 5 is a graph showing current vs. voltage characteristics of a gate insulating film whose thickness corresponds to 1.5 nm in terms of the thickness of an oxide film, for the purpose of checking leakage currents from the gate. It can be seen from FIG. 5 that the gate insulating film according to the present embodiment causes a leakage current that is smaller than a gate insulating film comprising only a pure oxide film, by one figure position. This is because the permittivity is increased by nitrogen introduced into the oxide film. Although not shown by the graph, the inventor has confirmed that the same effect is achieved by a gate insulating film whose thickness corresponds to 2.0 nm in terms of the thickness of an oxide film.

FIG. 6 is a graph showing a threshold voltage, as it varies from a theoretical value, of a p-MOS transistor which has a gate insulating film whose thickness corresponds to 1.5 nm in terms of the thickness of an oxide film. A study of FIG. 6 indicates that with the conventional gate insulating film comprising only an oxide film having a thickness of 1.5 nm, the threshold value is largely shifted from the theoretical value in the positive direction, showing that an impurity of boron is diffused from the p-type gate electrode into the silicon substrate, and that according to the present embodiment, the threshold value is not substantially different from the theoretical value, showing that almost no boron is diffused into the silicon substrate.

The characteristics shown in FIGS. 5 and 6 can also be achieved by the conventional process A. According to the conventional process A, while it is necessary to treat the assembly at a very high temperature in order to introduce a sufficient amount of nitrogen into the oxide film according to an oxidizing and nitriding step using an NO gas, it is possible to increase the permittivity up to about 5.0 with the introduced nitrogen. The increased permittivity is effective to reduce the leakage current and prevent the threshold voltage from varying, as with the first embodiment of the present invention.

However, the difference between the conventional process A and the process according to the first embodiment of the present invention due to different steps of nitriding the oxide film clearly manifests itself in the reliability of the gate insulating film and the performance of the transistor.

First, the reliability of the gate insulating film will be described below. FIG. 7 is a graph showing the relationship between times up to gate insulating film breakdown and accumulated fault rates (Weibull index) at the time electric stresses are continuously imposed on the gate insulating film. The illustrated relationship is also referred to as TDDB characteristics, and indicates that as the time up to breakdown is longer, the service life is longer and the reliability is higher. In a test to obtain the data shown in FIG. 7, a current having a current density of 1 A/cm² was passed through the gate insulating film at 125° C. in each of 89 devices, and an accumulated fault rate was checked upon elapse of a preset time. It can be seen from FIG. 7 that the devices manufactured according to the first embodiment of the present invention have a service life that is about one figure position longer than the service life of the devices manufactured according to the conventional process A. The longer service life is achieved because an impurity of boron of the gate electrode does not enter the gate insulating film. Specifically, according to the conventional process A, since the oxynitride film is present in or near the interface between the oxide film and the silicon substrate, boron is diffused into its region, and hence tends to enter and be accumulated in the gate insulating film. According to the first embodiment of the present invention, since the oxynitride film is present in the surface of the gate insulating film, no boron enters the gate insulating film. Inasmuch as the introduction of boron results in a reduction in the device reliability, the process according to the first embodiment is better than the conventional process A because the former process is capable of stopping the introduction of boron at the oxynitride film in the surface of the gate insulating film.

If nitrogen is present in the interface between the oxide film and the silicon substrate, then a defect referred to as an interface state occurs in the interface. The interface state greatly lowers the mobility of the carrier of the transistor and results in a reduction of the ON current of the transistor, lowering the switching operation of the transistor. According to the first embodiment of the present invention, since no nitrogen is present in the vicinity of the interface between the oxide film and the silicon substrate, the mobility of the carrier is not reduced, and the resulting device is capable of operating at a high speed.

2nd Embodiment

In the first embodiment, two gate insulating films whose thicknesses differ from each other by 0.5 nm are formed on one silicon substrate. Insofar as the conventional process B is not employed, i.e., if the oxide film is nitrided after the assembly is sufficiently thermally oxidized in the formation of gate insulating films, then gate insulating films with various thickness differences can be formed. FIG. 8 is a graph showing various film thickness differences that can be achieved at the time oxide films are formed under constant oxidizing conditions and varying fluorine injecting conditions. As shown in FIG. 8, if the fluorine dose is reduced, then it is possible to form gate insulating films whose thicknesses differ from each other by a small value of 0.2 nm, and if the fluorine dose is increased, then it is possible to form gate insulating films whose thicknesses differ from each other by a large value of 1.0 nm. For example, if the fluorine dose is set to 1×10¹⁵ atoms/m² upon the injection of fluorine ions in the first embodiment, then the oxide film is nitrided to the same depth (1.0 nm) as in the first embodiment, and gate insulating films having respective thicknesses corresponding to 1.5 nm and 2.5 nm in terms of the thicknesses of oxide films are formed.

3rd Embodiment

In the first embodiment, the surface of the oxide film is nitrided with radical nitrogen using a remote plasma source. However, the surface of the oxide film may be nitrided by any nitriding processes insofar as they nitride the surface layers of oxide films with a thickness difference into oxynitride films. For example, a process of depositing a nitride film using an ammonia gas and a silane gas according to CVD may be employed according to the present invention.

A process of fabricating a gate insulating film according to the above process will be described below with reference to FIGS. 9a through 9e. It is assumed that gate insulating films having respective thicknesses corresponding to 1.5 nm and 2.5 nm in terms of the thicknesses of oxide films are to be formed.

As shown FIG. 9a, as with the first embodiment of the present invention, silicon substrate 31 includes first region 31a where a gate insulating film of a greater thickness is to be formed and second region 31b where a gate insulating film of a smaller thickness is to be formed. Photoresist layer 32 is formed only on second region 31b. Then, as shown in FIG. 9b, fluorine is injected into the assembly to introduce fluorine atoms 33 into silicon substrate 31 in first region 31a and into photoresist layer 32 over second region 31b. In this embodiment, fluorine is injected with a dose of 1×10¹⁵ atoms/cm².

Then, as with the first embodiment of the present invention, a chemical oxide film is formed all over silicon substrate 31 by cleaning same. Thereafter, as shown in FIG. 9c, the chemical oxide film is removed to exposed the surface of silicon substrate 31.

Thereafter, as shown in FIG. 9d, thermal oxide film 35 is formed on the surface of silicon substrate 31 as with the first embodiment of the present invention under such conditions that a thermal oxide film is formed to a thickness of 1.0 nm in second region 31b. Thermal oxide film 35 in first region 31a has a thickness of 1.5 nm.

Then, as shown in FIG. 9e, CVD nitride film 36 is formed to a thickness of about 1.0 nm on thermal oxide film 35. CVD nitride film 36 may be formed in an atmosphere of 700° C. and 30 Torr using an LPVCD furnace. Thermal oxide film 35 and CVD nitride film 36 formed thereon jointly serve as gate insulating film 37.

In the third embodiment, the sufficient film thickness difference is achieved by oxidization, the nitride layer for preventing the impurity from reaching the silicon substrate is present in the surface layer of the gate insulating film, and the interface between the oxide film and the silicon substrate comprises a pure oxide film. Thus, as with the first embodiment, the leakage current is reduced, the threshold voltage is prevented from unduly varying, the channel mobility is prevented from being degraded, and the device reliability is increased.

4th Embodiment

In the first through third embodiments, two types of gate insulating films of different thicknesses are formed on one silicon substrate. The principles of the present invention are also applicable to the formation of three or more types of gate insulating films of different thicknesses.

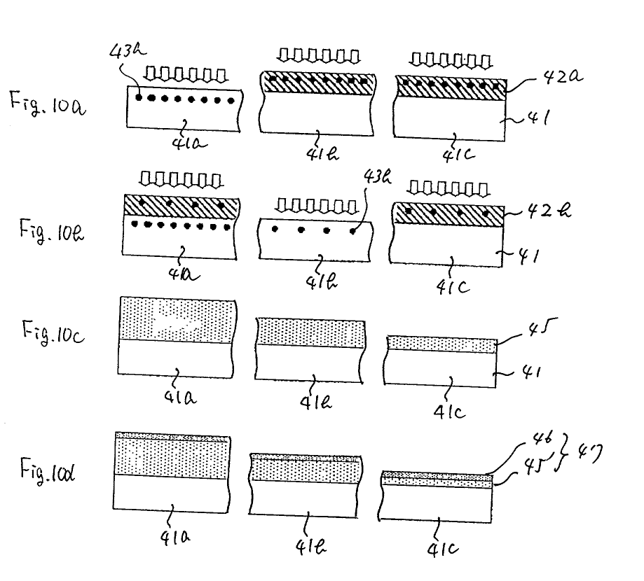

A process of forming three types of gate insulating films of respective thicknesses which correspond to 1.5 nm, 2.0 nm, and 2.5 nm, respectively, in terms of the thicknesses of oxide films will be described below with reference to FIGS. 10a through 10d.

As shown in FIG. 10a, a silicon substrate 41 h includes first region 41a where a gate insulating film having a thickness of 2.5 nm is to be formed, second region 41b where a gate insulating film having a thickness of 2.0 nm is to be formed, and third region 41c where a gate insulating film having a thickness of 1.5 nm is to be formed. Photoresist layer 42a is formed on second and third regions 41b, 41c. Then, fluorine is injected into the assembly to introduce fluorine atoms 43a into silicon substrate 41 only in first region 41a. At this time, fluorine is injected with a dose of 1×10¹⁵ atoms/cm² in an accelerating electric field of 3 keV.

Then, photoresist layer 42a is removed. As shown in FIG. 10b, new photoresist layer 42b is formed on first region 41a and third region 41c. When fluorine is then injected into the assembly, fluorine atoms 43b are introduced into silicon substrate 41 only in second region 41b. At this time, fluorine is injected with a dose of 5×10¹⁴ atoms/cm² in an accelerating electric field of 3 keV.

Thereafter, photoresist layer 42b is removed. After the assembly is cleaned as with the first embodiment of the present invention, the assembly is thermally oxidized under such conditions that a thermal oxide film is formed to a thickness of 1.7 nm in third region 41c, thus forming thermal oxide film 45 on the surface of silicon substrate 41, as shown in FIG. 10c. Since fluorine atoms 43a, 43b have been injected into first and second regions 41a, 41b, respectively, the thickness of thermal oxide film 45 is 2.7 nm in first region 41a, 2.2 nm in second region 41b, and 1.7 nm in third region 41c after the above thermal oxidizing step. The thickness of the thermal oxide film can be varied by varying fluorine injecting conditions.

Then, as with the first embodiment of the present invention, the surface layer of thermal oxide film 45 is nitrided to produce gate insulating film 47 which has oxynitride film 46 having a thickness of 1.0 nm on thermal oxide film 45′. The thickness of gate insulating film 47 corresponds to 2.5 nm in first region 41a, 2.0 nm in second region 41b, and 1.5 nm in third region 41c in terms of the thicknesses of oxide films.

5th Embodiment

When three types of gate insulating films of respective thicknesses are formed on one silicon substrate, the thickness of one of the gate insulating films may be widely different from the thickness of another one of the gate insulating films. For example, if a transistor has an I/O interface power supply voltage of 3.3 V, then a gate insulating film thereof often needs to have a thickness of about 7.5 nm. If the thickness of a thinnest gate insulating film is 1.5 nm, then it is difficult to provide a film thickness difference of 6.0 nm only by injecting fluorine. For fabricating such a transistor, the thinnest gate insulating film and the next thinnest gate insulating film may be formed by any one of the processes according to the above embodiments, and the thickest gate insulating film may be formed by another process.

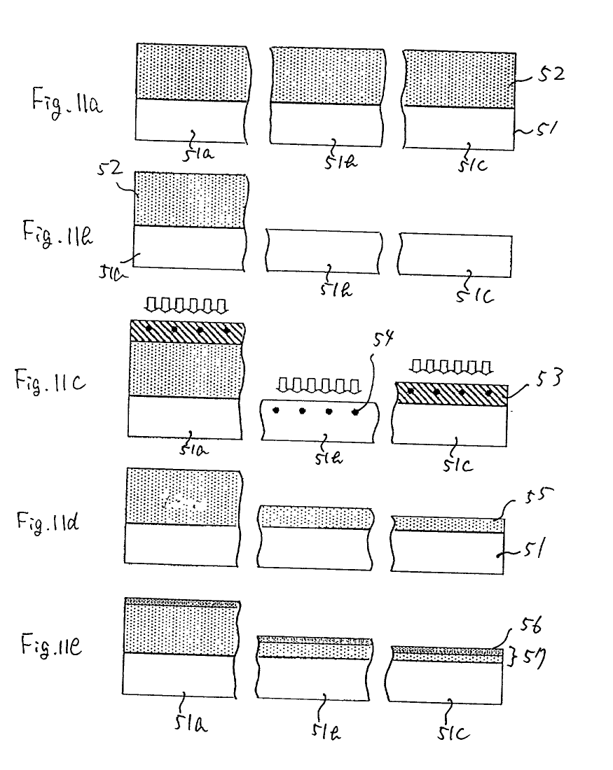

A process of forming a gate insulating film having a thickness in a region which is widely different from the thicknesses in other regions will be described below with reference to FIGS. 11a through 11e.

As shown in FIG. 11a, oxide film 52 is formed to a thickness of 7.3 nm on the surface of silicon substrate 51 according to a usual process.

Then, as shown in FIG. 11b, oxide film 52 is removed from second and third regions 51b, 51c by a photoresist processing sequence, leaving oxide film 52 on first region 51a.

Then, as shown in FIG. 11c, photoresist layer 53 is formed only on first region 51a and third region 51c. Thereafter, fluorine is injected into the assembly to introduce fluorine atoms 54 only into second region 51b. At this time, fluorine is injected with a dose of 5×10¹⁴ atoms/cm² in an accelerating electric field of 3 keV.

Thereafter, photoresist layer 53 is removed. After the assembly is cleaned as with the first embodiment of the present invention, the assembly is thermally oxidized under such conditions that a thermal oxide film is formed to a thickness of 1.7 nm in third region 51c, thus forming thermal oxide film 55 on the surface of silicon substrate 51, as shown in FIG. 11d. Since fluorine atoms 54 have been injected into second region 51b, the thickness of thermal oxide film 55 is 2.2 nm in second region 51b. Because the oxide film has already been formed on first region 51a, the film thickness is slightly increased to 7.7 mm by the thermal oxidizing step.

The, the assembly is nitrided as with the first embodiment of the present invention to form gate insulating film 57 having oxynitride film 56 of a thickness of 1.0 nm in its surface layer, as shown in FIG. 11e. The thickness of gate insulating film 57 corresponds to 7.5 nm in first region 51a, 2.0 nm in second region 51b, and 1.5 nm in third region 51c in terms of the thicknesses of oxide films.

6th Embodiment

For forming three types of gate insulating films of respective thicknesses on one silicon substrate, a thickest gate insulating film and an electrode may first be formed in a region, and other two gate insulating films of different thicknesses may be formed in other regions according to any one of the processes according to the first through third embodiments of the present invention.

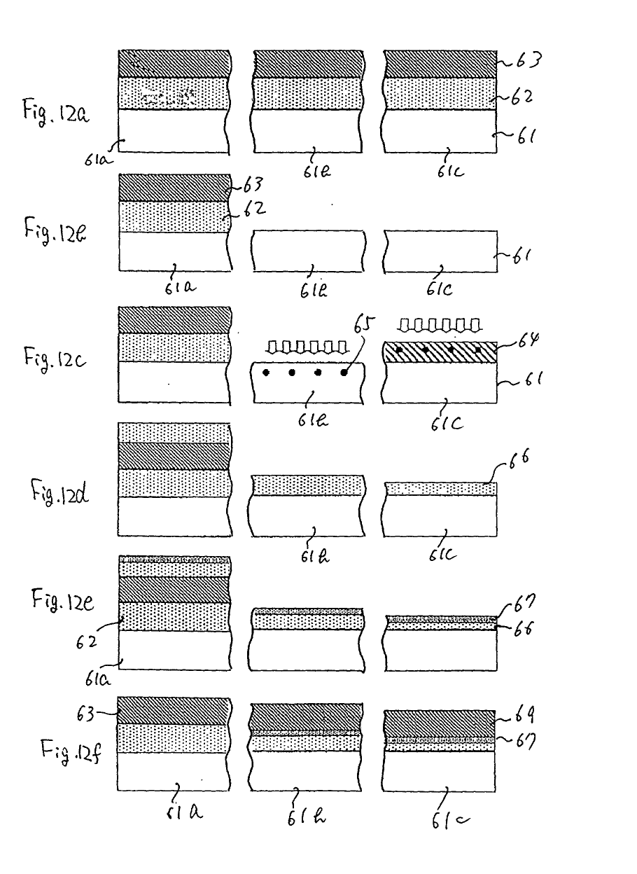

A process of forming three gate insulating films having different thicknesses will be described below with reference to FIGS. 12a through 12f.

As shown in FIG. 12a, oxide film 62 is formed on the surface of silicon substrate 61, and then polysilicon film 63 serving as an electrode is formed on oxide film 62. Oxide film 62 has a thickness which is equal to the thickness of a gate insulating film in first region 61a, which is a region where a thickest gate insulating film is formed.

Oxide film 62 and polysilicon film 63 are removed from second and third regions 61b, 61c, leaving those on first region 61a.

The assembly is then processed in substantially the same manner as with the process according to the fifth embodiment subsequent to the step of injecting fluorine.

Specifically, as shown in FIG. 12c, photoresist layer 64 is formed on third region 61c, and fluorine atoms 65 are injected into silicon substrate 61 only in second region 61b.

Then, photoresist layer 64 is removed, and the assembly is cleaned and then thermally oxidized to form a thermal oxide film 66, as shown in FIG. 12d. Thermal oxide film 66 has different thicknesses over second region 61a and third region 61c.

Thereafter, thermal oxide film 66 is nitrided to form a gate insulating film having oxynitride film 67 in the surface layer of thermal oxide film 66, as shown in FIG. 12e.

Then, as shown in FIG. 12f, polysilicon film 69 serving as an electrode is formed on the surface of oxynitride film 67. Thereafter, the structure above first polysilicon film 63 is removed from first region 61a.

The above process produces a gate insulating film comprising pure oxide film 62 over first region 61a and gate insulating films having oxynitride film 67 in the surface layer of thermal oxide film 66 and also having different thicknesses over second region 61b and third region 61c, respectively. Since the oxide film over first region 61a is formed completely independently of the gate insulating films over second region 61b and third region 61c, the thickness of the oxide film can freely be selected.

While the first through sixth embodiments of the present invention have specifically been described above, they may be applied to the fabrication of a semiconductor device having four or more types of gate insulating films having different thicknesses.

Although certain preferred embodiments of the present invention have been shown and described in detail, it should be understood that various changes and modifications may be made without departing from the spirit or scope of the appended claims.

What is claimed is:

1. A method of manufacturing a semiconductor device having a plurality of gate insulating films of different thicknesses on a semiconductor substrate, comprising the steps of:
injecting fluorine into a region of a semiconductor substrate other than a region of the semiconductor substrate where a thinnest gate insulating film is to be formed, among a plurality of regions where gate insulating films are to be formed;
oxidizing the semiconductor substrate with fluorine injected therein to form an oxide film in said plurality of regions; and
nitriding a surface of said oxide film to turn a surface layer thereof into an oxynitride film or form a nitride film on the surface of said oxide film.

2. A method according to claim 1, wherein said step of injecting fluorine comprises the step of:
setting conditions for injecting fluorine such that the gate insulating films formed on said semiconductor substrate have a thickness of at least 0.2 nm.

3. A method according to claim 1, wherein said step of nitriding the surface of said oxide film further comprises the step of:
introducing radical nitrogen excited by plasma into the surface of said oxide film.

4. A method of manufacturing a semiconductor device having a plurality of gate insulating films of different thicknesses on a semiconductor substrate, comprising the steps of:
forming a first oxide film on a surface of a semiconductor substrate;
removing said first oxide film from regions of the semiconductor substrate other than a region of the semiconductor substrate where a thickest gate insulating film is to be formed, among a plurality of regions where gate insulating films are to be formed;
injecting fluorine into the region other than the region where a thinnest gate insulating film is to be formed, among the regions of the semiconductor substrate from which said first oxide film has been removed;
oxidizing the semiconductor substrate with fluorine injected therein to form a second oxide film in said plurality of regions; and
nitriding a surface of said second oxide film to turn a surface layer thereof into an oxynitride film or form a nitride film on the surface of said second oxide film.

5. A method according to claim 4, wherein said step of injecting fluorine comprises the step of:
setting conditions for injecting fluorine such that the gate insulating films formed on said semiconductor substrate have a thickness of at least 0.2 nm.

6. A method according to claim 4, wherein said step of nitriding the surface of said second oxide film further comprises the step of:
introducing radical nitrogen excited by plasma into the surface of said second oxide film.

7. A method of manufacturing a semiconductor device having a plurality of gate insulating films of different thicknesses on a semiconductor substrate, comprising the steps of:
forming a first oxide film on a surface of a semiconductor substrate;
forming a first polysilicon film on a surface of said first oxide film;
removing said first polysilicon film and said first oxide film from regions of the semiconductor substrate other than a region of the semiconductor substrate where a thickest gate insulating film is to be formed, among a plurality of regions where gate insulating films are to be formed;
injecting fluorine into the region other than the region where a thinnest gate insulating film is to be formed, among the regions of the semiconductor substrate from which said first polysilicon film and said first oxide film have been removed;
oxidizing the semiconductor substrate with fluorine injected therein to form a second oxide film in said plurality of regions;
nitriding a surface of said second oxide film to turn a surface layer thereof into an oxynitride film or form a nitride film on the surface of said second oxide film;
forming a second polysilicon film on a surface of said oxynitride film or a surface of said nitride film; and
removing a structure above said first polysilicon film from the region where the thickest gate insulating film is to be formed, among said plurality of regions.

8. A method according to claim 7, wherein said step of injecting fluorine comprises the step of:
setting conditions for injecting fluorine such that the gate insulating films formed on said semiconductor substrate have a thickness of at least 0.2 nm.

9. A method according to claim 7, wherein said step of nitriding the surface of said second oxide film further comprises the step of:
introducing radical nitrogen excited by plasma into the surface of said oxide film.

10. A semiconductor device having a plurality of gate insulating films of different thicknesses including at least an oxide film on a surface of a semiconductor substrate, comprising:
a semiconductor substrate;
a plurality of oxide films formed respectively in different regions in a surface of said semiconductor substrate to respective different thicknesses; and
a plurality of oxynitride films or nitride films produced by nitriding surfaces of said oxide films.

11. A semiconductor device according to claim 10, wherein said oxynitride films or nitride films are formed on the surfaces of the oxide films other than the thickest oxide film.

12. A semiconductor device according to claim 10, wherein the thicknesses of said oxide films are different from each other by at least 0.2 nm.
